(19) United States
(12) Patent Application Publication
(10) Pub. No.: US 2025/0275455 A1
(43) Pub. Date: Aug. 28, 2025

(54) DISPLAY DEVICE

(71) Applicant: LG Display Co., Ltd., Seoul (KR)

(72) Inventors: KyungKook JANG, Goyang-si (KR); SeongHan HWANG, Goyang-si (KR); YounSik KIM, Uijeongbu-si (KR); DaBin KIM, Changwon-si (KR)

(73) Assignee: LG Display Co., Ltd., Seoul (KR)

(21) Appl. No.: 19/019,415

(22) Filed: Jan. 13, 2025

(30) Foreign Application Priority Data
Feb. 26, 2024 (KR) 10-2024-0027331

(51) Int. Cl. H10K 59/80; H10K 59/122; H10K 59/60; H10K 102/00

(52) U.S. Cl. CPC H10K 59/8792; H10K 59/122; H10K 59/60; H10K 59/877; H10K 2102/331

(57) ABSTRACT

According to an aspect of the present disclosure, a display device includes a substrate; a planarization layer disposed on the substrate; a first electrode disposed on the planarization layer; a light reinforcement layer disposed on the first electrode and the planarization layer; a bank which is disposed on the light reinforcement layer and includes an optical material; a light emitting layer disposed on the first electrode; and a second electrode disposed on the light emitting layer and the bank. The light reinforcement layer may cover at least a part of the first electrode.

### CROSS-REFERENCE TO RELATED APPLICATIONS

This application claims the benefit of and priority to Korean Patent Application No. 10-2024-0027331 filed on Feb. 26, 2024, in the Korean Intellectual Property Office, the entire contents of which are incorporated herein by reference for all purposes.

### BACKGROUND

### 1. Technical Field

The present disclosure relates to a display device.

### 2. Description of the Related Art

For the display device, it is required to have a low reflectance to external light to allow a user to easily identify information displayed by the display device.

The display device may include various circuit elements to display images. When external light is irradiated on the display device, light is reflected by the circuit element included in the display device so that it is difficult for a user to identify information displayed on the display device.

The description of the related art should not be assumed to be prior art merely because it is mentioned in or associated with this section. The description of the related art includes information that describes one or more aspects of the subject technology, and the description in this section does not limit the invention.

### SUMMARY

An aspect of the present disclosure is to provide a display device which reduces reflection of external light.

Another aspect of the present disclosure is to provide a display device which absorbs light having a wavelength of a visible ray band to emit infrared light.

Another aspect of the present disclosure is to provide a display device which improves infrared light emitting characteristic using a light reinforcement layer.

Aspects of the present disclosure are not limited to the above-mentioned aspects, and other aspects, which are not mentioned above, can be clearly understood by those skilled in the art from the following descriptions.

In order to achieve the aspects as described above, according to an aspect of the present disclosure, a display device includes a substrate; a planarization layer disposed on the substrate; a first electrode disposed on the planarization layer; a light reinforcement layer disposed on the first electrode and the planarization layer; a bank which is disposed on the light reinforcement layer and includes an optical material; a light emitting layer disposed on the first electrode; and a second electrode disposed on the light emitting layer and the bank, and the light reinforcement layer may cover at least a part of the first electrode.

Other detailed matters of the example embodiments are included in the detailed description and the drawings.

According to one or more aspects of the present disclosure, reflection of external light is reduced to improve a user's visibility.

According to one or more aspects of the present disclosure, a light reinforcement layer is provided below a bank which generates light in infrared or near-infrared band using primary light to extract secondary light toward the front surface.

The effects of the present disclosure are not limited to the contents exemplified above, and more various effects are included in the present specification.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view of a display device according to an example embodiment of the present disclosure;

FIG. 2 is a block diagram of a display device according to an example embodiment of the present disclosure;

FIG. 3 is a schematic cross-sectional view of a display panel of a display device according to an example embodiment of the present disclosure;

FIG. 4 is a schematic plan view of a first substrate of a display device according to an example embodiment of the present disclosure;

FIG. 5 is a plan view of a touch sensing layer of a display device according to an example embodiment of the present disclosure;

FIG. 6 is a cross-sectional view taken along line I-I′ of FIG. 5;

FIG. 7 is a schematic enlarged plan view of a display device according to an example embodiment of the present disclosure;

FIG. 8 is a cross-sectional view taken along line A-A′ of FIG. 7;

FIG. 9 is a cross-sectional view of an area B of FIG. 8 according to an example embodiment of the present disclosure;

FIG. 10 is a cross-sectional view for explaining an example of generating primary light of a display device according to an example embodiment of the present disclosure;

FIG. 11 is a cross-sectional view for explaining an example that secondary light of a display device according to an example embodiment of the present disclosure is generated and is blocked by a light reinforcement layer;

FIG. 12 is a schematic enlarged plan view of a display device according to another example embodiment of the present disclosure;

FIG. 13 is a schematic cross-sectional view of the light reinforcement layer of a display device according to another example embodiment of the present disclosure;

FIG. 14 is a cross-sectional view taken along line B-B′ of FIG. 12;

FIGS. 15 and 16 are schematic enlarged plan views of a display device according to still another example embodiment of the present disclosure;

FIG. 17 is a schematic cross-sectional view of a light reinforcement layer of a display device according to still another example embodiment of the present disclosure;

FIG. 18 is a cross-sectional view which is commonly applicable to a cross-section taken along line C-C′ of FIG. 15 and a cross-section taken along line D-D′ of FIG. 16; and

FIG. 19 schematically illustrates a cross-section of a display device including a photo diode according to still another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

In addition, when described as ‘coupled’ or ‘connected’, it may include being ‘coupled’ or ‘connected’ through one or more other components located between the two components, unless ‘immediately’ or ‘directly’ is used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

A transistor used for a display device according to example embodiments of the present disclosure may be implemented by any one transistor of n-channel transistors (NMOS) and p-channel transistors (PMOS). The transistor may be implemented by an oxide semiconductor transistor having an oxide semiconductor as an active layer or an LTPS transistor having a low temperature poly-silicon (LTPS) as an active layer. The transistor may include at least a gate electrode, a source electrode, and a drain electrode. The transistor may be implemented as a thin film transistor (TFT) on a display panel. In the transistor, carriers flow from the source electrode to the drain electrode. In the case of the n-channel transistor NMOS, since the carriers are electrons, in order to allow the electrons to flow from the source electrode to the drain electrode, a source voltage may be lower than a drain voltage. The current in the n-channel transistor NMOS flows from the drain electrode to the source electrode and the source electrode may serve as an output terminal. In the case of the p-channel transistor (PMOS), since the carriers are holes, in order to allow the holes to flow from the source electrode to the drain electrode, a source voltage may be higher than a drain voltage. In the p-channel transistor PMOS, the holes flow from the source electrode to the drain electrode so that current flows from the source to the drain and the drain electrode serves as an output terminal. Accordingly, the source and the drain may be switched in accordance with the applied voltage so that it should be noted that the source and the drain of the transistor are not fixed. In the present specification, it is assumed that the transistor is an n-channel transistor NMOS, but is not limited thereto so that the p-channel transistor may be used and thus a circuit configuration may be changed.

A gate signal of transistors which are used as switching elements may swing between a gate-on voltage and a gate-off voltage. The gate-on voltage is set to be higher than a threshold voltage Vth of the transistor and the gate off voltage is set to be lower than the threshold voltage Vth of the transistor. The transistor is turned on in response to the gate-on voltage and may be turned off in response to the gate-off voltage. In the case of the n-channel transistor NMOS, the gate-on voltage is a gate high voltage VGH and the gate-off voltage may be a gate low voltage VGL. In the case of the p-channel transistor PMOS, the gate-on voltage is a gate low voltage VGL and the gate-off voltage may be a gate high voltage VGH.

Hereinafter, a display device according to example embodiments of the present disclosure will be described in detail with reference to accompanying drawings.

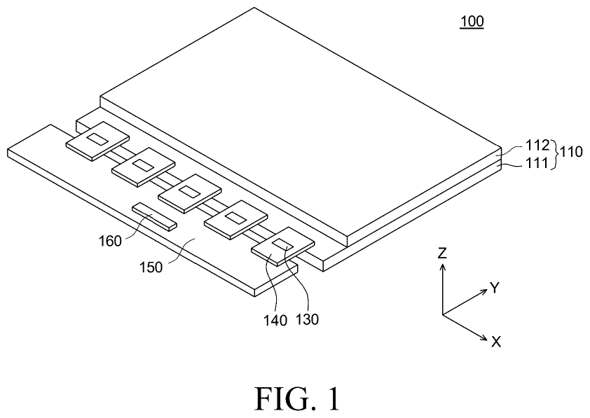

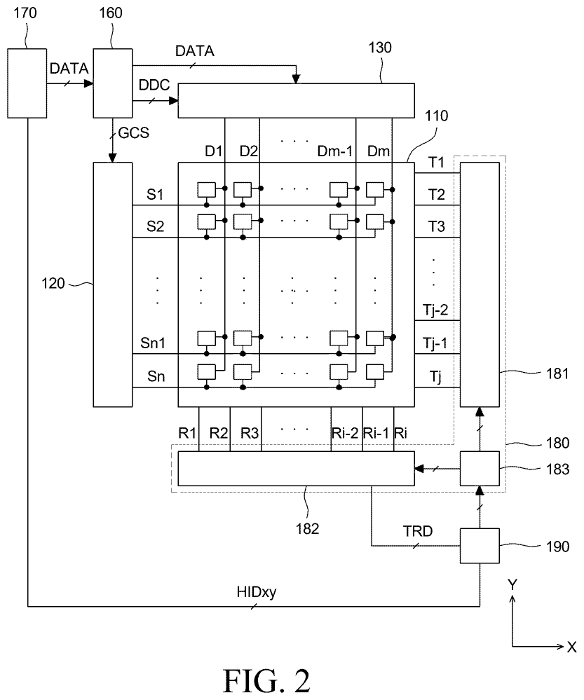

FIG. 1 is a perspective view of a display device according to an example embodiment of the present disclosure. FIG. 2 is a block diagram of a display device according to an example embodiment of the present disclosure. Specifically, FIG. 1 is a perspective view illustrating a display device according to an example embodiment of the present disclosure and FIG. 2 is a block diagram illustrating a display device according to an example embodiment of the present disclosure.

Referring to FIGS. 1 and 2, the display device 100 according to the example embodiment of the present disclosure includes a display panel 110, a scan driver 120, a data driver 130, a timing controller 160, a host system 170, a touch driver 180, and a touch coordinate calculating unit 190.

The display device 100 according to the example embodiment of the present disclosure may be implemented by a flat display device, such as a liquid crystal display (LCD), a field emission display (FED), an organic light emitting display (OLED), or a micro LED. Hereinafter, it is described by assuming that the display device 100 according to various example embodiments of the present disclosure is an organic light emitting display, but the type of the display device 100 is not limited thereto.

The display panel 110 includes a display area DA which is an area in which a plurality of pixels P is disposed to display images. In the display panel 110, data lines D1 to Dm (m is a positive integer of 2 or larger) and scan lines S1 to Sn (n is a positive integer of 2 or larger) are provided. The data lines D1 to Dm may be disposed to intersect the scan lines S1 to Sn. The plurality of pixels P may be formed in an area defined by an intersecting structure of the scan lines and the data lines.

Each of the plurality of pixels P of the display panel 110 is connected to any one of the data lines D1 to Dm and any one of the scan lines S1 to Sn. Each of the plurality of pixels P of the display panel 110 may include a driving transistor, a scan transistor, a light emitting diode, and a capacitor. The driving transistor adjusts a drain-source current according to a data voltage applied to the gate electrode. The scan transistor is turned on by a scan signal of the scan line to supply a data voltage of the data line to a gate electrode of the driving transistor. The light emitting diode emits light according to the drain-source current of the driving transistor and the capacitor stores a voltage of the gate electrode of the driving transistor. By doing this, each of the plurality of pixels P may emit light according to a current supplied to the organic light emitting diode.

The scan driver 120 receives a scan control signal GCS from the timing controller 160. The scan driver 120 supplies scan signals to the scan lines S1 to Sn according to the scan control signal GCS.

The scan driver 120 may be formed in a gate in panel (GIP) manner in a non-display area NDA at one or both outsides of the display area DA of the display panel 110. The scan driver 120 may be formed in the display area DA of the display panel 110 in a gate in active area (GIA) manner. Alternatively, the scan driver 120 may be manufactured as a driving chip to be mounted in a flexible film or attached in a non-display area NDA at one or both outsides of the display area DA of the display panel 110 in a tape automated bonding (TAB) manner.

The data driver 130 receives digital video data DATA and a data control signal DDC from the timing controller 160. The data driver 130 converts digital video data DATA into an analog positive/negative data voltage according to the data control signal DDC to supply the converted data voltage to the data lines. That is, a pixel P to be supplied with data voltages is selected by scan signals of the scan driver 120 and data voltages are supplied to the selected pixel P.

The data driver 130 may include a plurality of source drive ICs. Each of the plurality of source drive ICs may be mounted in the flexible film 140 in the chip on film (COF) or chip on plastic (COP) manner. The flexible film 140 is attached onto pads provided in the non-display area NDA of the display panel 110 using an anisotropic conducting film and thus the plurality of source drive ICs may be connected to the pads.

The circuit board 150 may be attached to the plurality of flexible films 140. In the circuit board 150, a plurality of circuits which is implemented by driving chips may be mounted. For example, the timing controller 160 may be mounted on the circuit board 150. The circuit board 150 may be a printed circuit board or a flexible printed circuit board.

The timing controller 160 receives the digital video data DATA and the timing signals from the host system 170. The timing signals may include a vertical synchronization signal, a horizontal synchronization signal, a data enable signal, and a dot clock. The vertical synchronization signal is a signal which defines one frame period. The horizontal synchronization signal is a signal which defines one horizontal period required to supply data voltages to pixels in one horizontal pixel line of the display panel DIS. The data enable signal is a signal which defines a period when effective data is input. The dot clock is a signal which is repeated at a predetermined short cycle.

The timing controller 160 generates a data control signal DDC for controlling an operation timing of the data driver 130 and a scan control signal GCS for controlling an operation timing of the scan driver 120 based on timing signals to control the operation timings of the scan driver 120 and the data driver 130. The timing controller 160 outputs the scan control signal GCS to the scan driver 120 and outputs the digital video data DATA and the data control signal DDC to the data driver 130.

The host system 170 may be implemented by a navigation system, a set-top box, a DVD player, a Blu-ray player, a personal computer (PC), a home theater system, a broadcasting receiver, and a phone system. The host system 170 includes a system on chip (SoC) embedded with a scaler to convert digital video data DATA of an input image into a format suitable to be displayed on the display panel 110. The host system 170 transmits the digital video data DATA and the timing signals to the timing controller 160.

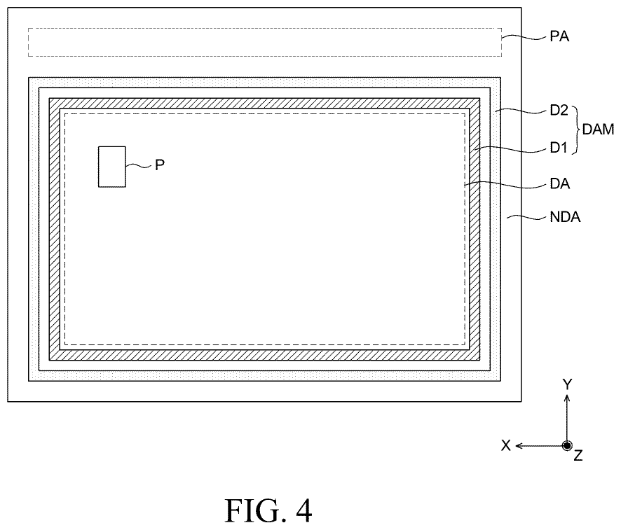

In the display panel 110, first and second touch electrodes may be formed other than the data lines D1 to Dm and the scan lines S1 to Sn. The first touch electrodes may be formed to intersect the second touch electrodes. The first touch electrodes may be connected to the first touch driver 181 through the first touch lines T1 to Tj (j is a positive integer of 2 or larger). The second touch electrodes may be connected to the second touch driver 182 through the second touch lines R1 to Ri (i is a positive integer of 2 or larger). A touch sensor may be formed in each of intersections of the first touch electrodes and the second touch electrodes. In the example embodiment of the present disclosure, even though it is exemplified that the touch sensor is implemented by mutual capacitance, it should be noted that it is not limited thereto. The first and second touch electrodes will be described in detail below with reference to FIG. 4.

The touch driver 180 supplies a driving pulse to the first touch electrodes through the first touch lines T1 to Tj and senses a charge variance of each of the touch sensors through the second touch lines R1 to Ri. That is, in FIG. 2, it has been mainly described that the first touch lines T1 to Tj are Tx lines which supply the driving pulse and the second touch lines R1 to Ri are Rx lines which sense the charge variance of each of the touch sensors.

The touch driver 180 includes a first touch driver 181, a second touch driver 182, and a touch controller 183. The first touch driver 181, the second touch driver 182, and the touch controller 183 may be integrated in a read-out IC (ROIC).

The first touch driver 181 selects a touch line from the first touch lines T1 to Tj under the control of the touch controller 183 and supplies the driving pulse to the selected touch line. For example, the first touch driver 181 may sequentially supply driving pulses to the first touch lines T1 to Tj.

The second touch driver 182 selects a touch line from the second touch lines R1 to Ri which receive charge variances of the touch sensors under the control of the touch controller 183, and receives charge variances of the touch sensors through the selected touch line. The second touch driver 182 samples the charge variances of the touch sensors received through the second touch lines R1 to Ri to convert the charge variances into touch raw data (TRD) which is digital data.

The touch controller 183 may generate a Tx setup signal to set a first touch line T1 to Tj to which the driving pulse is output in the first touch driver 181 and a Rx setup signal to set a second touch line R1 to Ri which receives a touch sensor voltage in the second touch driver 182. Further, the touch controller 182 generates timing control signals to control the operation timings of the first touch driver 181 and the second touch driver 182.

The touch coordinate calculating unit 190 receives touch low data TRD from the touch driver 180. The touch coordinate calculating unit 190 calculates a touch coordinate(s) according to a touch coordinate calculating method and outputs touch coordinate data HIDxy including information of the touch coordinate(s) to the host system 170.

The touch coordinate calculating unit 190 may be implemented by a micro controller unit (MCU). The host system 170 analyzes touch coordinate data HIDxy input from the touch coordinate calculating unit 190 to run an application program associated with a coordinate at which touch occurs by the user. The host system 170 transmits the digital video data DATA and the timing signals to the timing controller 160 according to the ran application program.

The touch driver 180 is included in the source drive ICs or is manufactured as a separate driving chip to be mounted on the circuit board 150. Further, the touch coordinate calculating unit 190 is manufactured as a driving chip to be mounted on the circuit board 150.

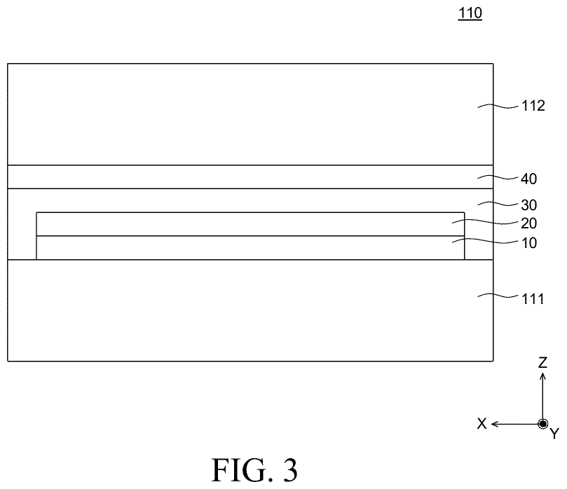

FIG. 3 is a schematic cross-sectional view of a display panel of a display device according to an example embodiment of the present disclosure. Specifically, FIG. 3 is a cross-sectional view schematically illustrating one side of the display panel of FIG. 1.

Referring to FIG. 3, the display panel 110 may include a first substrate 111, a second substrate 112, a thin film transistor layer 10 disposed between the first and second substrates 111 and 112, a light emitting diode layer 20, an encapsulation unit 30, and a touch sensing layer 40.

The first substrate 111 may be a plastic film or a glass substrate.

The thin film transistor layer 10 is disposed on the first substrate 111. The thin film transistor layer 10 may include scan lines, data lines, and thin film transistors. Each of the thin film transistors includes a gate electrode, a semiconductor layer, source and drain electrodes. When the scan driver is formed in a gate driver in panel (GIP) manner, the scan driver may be formed together with the thin film transistor layer 10.

The light emitting diode layer 20 is disposed on the thin film transistor layer 10. The light emitting diode layer 20 includes first electrodes, an organic light emitting layer, a second electrode, and banks. Each of the organic light emitting layers may include a hole transporting layer, an light emitting layer, and an electron transporting layer. In this case, when a voltage is applied to the first electrode and the second electrode, holes and electrons move to the light emitting layer through the hole transporting layer and the electron transporting layer and are combined in the light emitting layer to emit light. In the area where the light emitting diode layer 20 is disposed, the plurality of pixels P is disposed so that an area where the light emitting diode layer 20 is disposed may be defined as a display area DA. A surrounding area of the display area DA may be defined as a non-display area NDA.

The encapsulation unit 30 is disposed on the light emitting diode layer 20. The encapsulation unit 30 serves to suppress oxygen or moisture from permeating into the light emitting diode layer 20. The encapsulation unit 30 may include at least one inorganic film.

The touch sensing layer 40 is formed on the encapsulation unit 30. The touch sensing layer 40 includes first and second touch electrodes for sensing the user's touch and may include bridge electrodes which electrically connect the first touch electrodes or electrically connect the second touch electrodes.

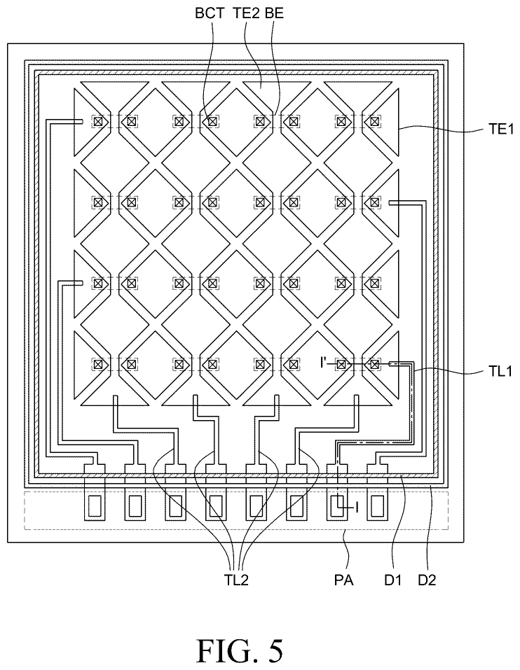

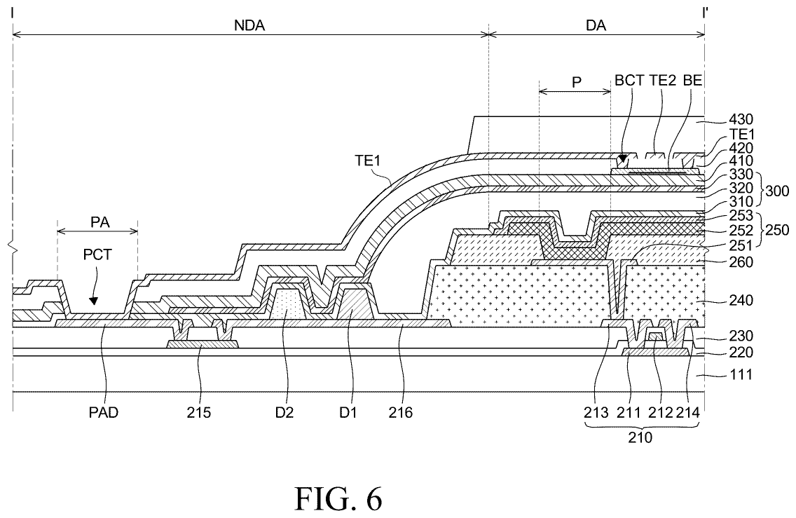

FIG. 4 is a schematic plan view of a first substrate of a display device according to an example embodiment of the present disclosure. FIG. 5 is a plan view of a touch sensing layer of a display device according to an example embodiment of the present disclosure. FIG. 6 is a cross-sectional view taken along line I-I′ of FIG. 5. Specifically, FIG. 4 is a plan view schematically showing a first substrate according to an example embodiment of the present disclosure and FIG. 5 is a plan view showing a touch sensing layer disposed on the first substrate. FIG. 6 is a cross-sectional view of a display device according to the example embodiment of the present disclosure and is a cross-sectional view taken along line I-I′ of FIG. 5.

Referring to FIGS. 4 to 6, the first substrate 111 is divided into a display area DA and the non-display area NDA and a plurality of pixels P is disposed in the display area DA. The non-display area NDA encloses the display area DA. A dam DAM and a pad area PA are provided in the non-display area NDA.

The thin film transistor layer 10 and the light emitting diode layer 20 are formed on the first substrate 111.

Referring to FIG. 6, the thin film transistor layer 10 includes a thin film transistor 210, a gate insulating layer 220, an interlayer insulating layer 230, and a planarization layer 240.

The thin film transistor 210 is disposed on the first substrate 111. The thin film transistor 210 includes an active layer 211, a gate electrode 212, a source electrode 213, and a drain electrode 214. In FIG. 6, the thin film transistor 210 is illustrated as a top gate type in which a gate electrode 212 is located above the active layer 211, but it is not limited thereto. That is, the thin film transistors 210 may be formed as a bottom gate type in which the gate electrode 212 is located below the active layer 211 or a double gate type in which the gate electrode 212 is located above and below the active layer 211.

The active layer 211 is disposed on the first substrate 111. The active layer 211 may be formed of a silicon based semiconductor material or an oxide based semiconductor material. A light shielding layer which blocks external light incident to the active layer 211 may be disposed between the first substrate 111 and the active layer 211.

The gate insulating layer 220 is disposed on the active layer 211. The gate insulating layer 220 may be formed of an inorganic film, for example, a silicon oxide (SiOₓ) layer, a silicon nitride (SiNₓ) layer, or a plurality of layers thereof.

The gate electrode 212 and the scan line 215 are disposed on the gate insulating layer 220. The gate electrode 212 and the scan line 215 may be formed of a single layer or a multi-layer formed of any one of molybdenum (Mo), aluminum (Al), chrome (Cr), gold (Au), titanium (Ti), nickel (Ni), neodymium (Nd), and copper (Cu), or an alloy thereof.

The interlayer insulating layer 230 may be disposed on the gate electrode 212 and the scan line 215. The interlayer insulating layer 230 may be formed of an inorganic film, for example, a silicon oxide (SiOₓ) layer, a silicon nitride (SiNₓ) layer, or a plurality of films thereof.

The source electrode 213, the drain electrode 214, the source drain line 216, and the pad electrode PAD may be disposed on the interlayer insulating layer 230. Each of the source electrode 213 and the drain electrode 214 may be connected to the active layer 211 through a contact hole passing through the gate insulating layer 220 and the interlayer insulating layer 230. Further, the source drain line 216 and the pad electrode PAD may be connected to the scan line 215 through a contact hole passing through the interlayer insulating layer 230. The source electrode 213, the drain electrode 214, the source drain line 216, and the pad electrode PAD may be formed of a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

A protective film for insulating the thin film transistor 210 may be disposed on the source electrode 213 and the drain electrode 214. The protective film may be formed of an inorganic film, for example, a silicon oxide (SiOₓ) layer, a silicon nitride (SiNₓ) layer, or a plurality of films thereof. The protective film may be omitted.

The planarization layer 240 for flattening a step due to the thin film transistor 210 may be disposed on the source electrode 213 and the drain electrode 214. The planarization layer 240 may be formed of an organic film, such as acryl resin, epoxy resin, phenolic resin, polyamide resin, or polyimide resin.

In the meantime, even though it is not illustrated in the drawing, a buffer film may be disposed between one surface of the first substrate 111 and the thin film transistor 210. The buffer film may be disposed on one surface of the first substrate 111 to protect the thin film transistors 210 and the light emitting diodes 250 from moisture permeating through the first substrate 111 which is vulnerable to the moisture permeation. One surface of the first substrate 111 may be a surface which is opposite to the second substrate 112. The buffer film is formed by a plurality of inorganic films which is alternately laminated. For example, the buffer film may be formed by alternately laminating a plurality of inorganic films of a silicon oxide (SiOₓ) layer, a silicon nitride (SiNₓ) layer, or a silicon oxy nitride (SiOₓN_{y}) layer. The buffer film may be omitted depending on the type of the first substrate 111 or a type of the thin film transistor 210.

Next, the light emitting diode layer 20 is disposed on the thin film transistor layer 10. The light emitting diode layer 20 includes a light emitting diode 250 and a bank 260.

The light emitting diode 250 and the bank 260 are disposed on the planarization layer 240. The light emitting diode 250 includes a first electrode 251, an organic light emitting layer 252, and a second electrode 253. The first electrode 251 is an anode electrode and the second electrode 253 may be a cathode electrode.

The first electrode 251 may be disposed on the planarization layer 240. The first electrode 251 is connected to the source electrode 213 of the thin film transistor 210 through a contact hole passing through the protective film and the planarization layer 240. The first electrode 251 may be formed of a metal material having a high reflectance, such as a laminated structure (Ti/Al/Ti) of aluminum and titanium, a laminated structure of aluminum and ITO (ITO/AI/ITO), an APC alloy, and a laminate structure of an APC alloy and ITO (ITO/APC/ITO). The APC alloy is an alloy of silver (Ag), palladium (Pd), and copper (Cu).

The bank 260 may be disposed on the planarization layer 240 so as to cover an edge of the first electrode 251 to partition the pixels P. That is, the bank 260 serves as a pixel definition film which defines pixels P. For example, the bank 260 may be formed of an organic film, such as acryl resin, epoxy resin, phenolic resin, polyamide resin, or polyimide resin.

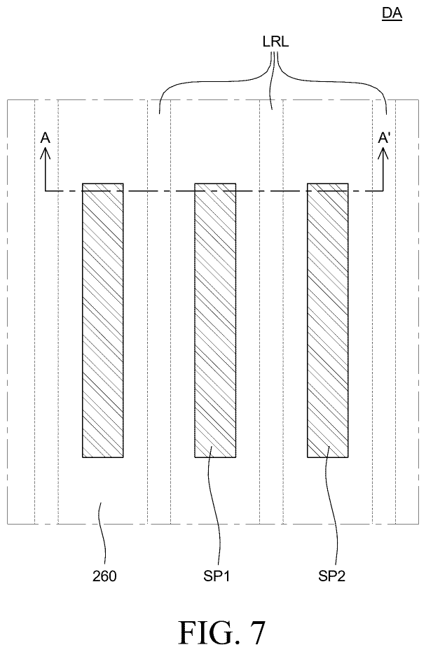

In the meantime, the bank 260 includes an optical material to absorb primary light and then emits light in other wavelength band and the bank 260 will be described below in more detail with reference to FIGS. 7 to 9.

The organic light emitting layer 252 is disposed on the first electrode 251 and the bank 260. The organic light emitting layer 252 may include a hole transporting layer, at least one light emitting layer, and an electron transporting layer. In this case, when a voltage is applied to the first electrode 251 and the second electrode 253, holes and electrons move to the light emitting layer through the hole transporting layer and the electron transporting layer and are combined in the light emitting layer to emit light.

The organic light emitting layer 252 may be formed of a white light emitting layer which emits white light. In this case, the organic light emitting layer 252 may be disposed so as to cover the first electrode 251 and the bank 260. Further, a color filter may be disposed on the second substrate 112.

Alternatively, the organic light emitting layer 252 includes a red light emitting layer which emits red light, a green light emitting layer which emits green light, and a blue light emitting layer which emits blue light. In this case, the organic light emitting layer 252 may be disposed in an area corresponding to the first electrode 251 and the color filter is not disposed on the second substrate 112.

The second electrode 253 is disposed on the organic light emitting layer 252. When the organic light emitting display device 100 is formed with a top emission structure, the second electrode 253 may be formed of a transparent metal material (TCO, transparent conductive material) which transmits light, such as ITO or IZO or a semi-transmissive conductive material such as magnesium (Mg), silver (Ag), or an alloy of magnesium (Mg) and silver (Ag). A capping layer may be disposed on the second electrode 253.

The encapsulation unit 30 is disposed on the light emitting diode layer 20 not only in the display area DA but also in the non-display area NDA of the first substrate 111. The encapsulation unit 30 includes a dam DAM and an encapsulation layer 300.

The dam DAM is disposed in the non-display area NDA to block the flow of the organic layer 320 which configures the encapsulation layer 300. To be more specific, the dam DAM is disposed so as to enclose the outer periphery of the display area DA to block the flow of the material of the organic layer 320 which configures the encapsulation layer 300. Further, the dam DAM is disposed in the non-display area NDA to block the flow of the material of the organic layer 320 so as not to allow the organic layer 320 which configures the encapsulation layer 300 to invade the pad electrode PAD exposed by a pad contact hole PCT. By doing this, the dam DAM may suppress the organic layer 320 from being exposed to the outside of the display device 100 or invading the pad electrode PAD.

The dam DAM may include a first dam D1 and a second dam D2.

The first dam D1 is disposed so as to enclose the outer periphery of the display area DA to primarily block the flow of the organic layer 320 which configures the encapsulation layer 300. Further, the first dam D1 is disposed between the display area DA and the pad area PA to primarily block the flow of the organic layer 320 so as to suppress the organic layer 320 from invading the exposed pad electrode PAD.

The second dam D2 is disposed so as to enclose the outer periphery of the first dam D1 and is spaced apart from the first dam D1 to be parallel to each other. The second dam D2 may secondarily block the organic layer 320 overflowing to the outer periphery of the first dam D1. By doing this, the first dam D1 and the second dam D2 effectively prevent the organic layer 320 from being exposed to the outside of the display device 100 or invading the exposed pad electrode PAD.

The dam DAM may be formed simultaneously with the planarization layer 240 or the bank 260 and may be formed of the same material as the planarization layer 240 or the bank 260. In this case, the dam DAM may be formed of an organic material, such as acryl resin, epoxy resin, phenolic resin, polyamide resin, or polyimide resin.

The encapsulation layer 300 is disposed so as to cover the display area DA to suppress the oxygen or moisture from permeating into the organic light emitting layer 252 and the second electrode 253. To this end, the encapsulation layer 300 may include at least one inorganic film and at least one organic film. For example, the encapsulation layer 300 may include a first inorganic layer 310, an organic layer 320, and a second inorganic layer 330.

The first inorganic layer 310 is disposed on the second electrode 253. The first inorganic layer 310 is disposed so as to cover the second electrode 253. The first inorganic layer 310 according to an example embodiment of the present disclosure covers the second electrode 253 and extends to the non-display area NDA to cover the dam DAM. Further, the first inorganic layer 310 according to the example embodiment of the present disclosure extends to the pad area PA disposed at the outside of the dam DAM, but exposes the pad electrode PAD without covering it. At this time, the first inorganic layer 310 according to the example embodiment of the present disclosure encloses the pad electrode PAD and more specifically, is disposed so as to enclose the outer periphery of the pad contact hole PCT which exposes the pad electrode PAD.

In the display device 100 according to the example embodiment of the present disclosure as described above, the first inorganic layer 310 extends to the pad area PA so that in order not to form the first inorganic layer 310 in the pad area PA, a mask which blocks the pad electrode PAD does not need to be disposed above the pad electrode PAD. Accordingly, in the display device 100 according to the example embodiment of the present disclosure, the mask is not needed to be disposed above the pad electrode PAD so that arcing phenomenon caused between a boundary surface of the mask and the pad electrode may be suppressed. Further, the high current which flows from the mask may be suppressed from flowing into the display device 100 along the pad electrode PAD to cause the defects.

As described above, in the display device 100 according to the example embodiment of the present disclosure, the first inorganic layer 310 is formed to entirely cover the pad electrode PAD and after forming the organic layer 320 and the second inorganic layer 330, the pad contact hole PCT is formed by an etching process using photoresist.

The organic layer 320 is disposed on the first inorganic layer 310. The organic layer 320 may be formed to have a thickness enough to suppress foreign particles from penetrating the first inorganic layer 310 to enter the organic light emitting layer 252 and the second electrode 253. The organic layer 320 may be formed by being applied in a liquid form by the inkjet process and then being subject to the hardening process.

The second inorganic layer 330 is disposed on the organic layer 320. The second inorganic layer 330 is disposed so as to cover the organic layer 320. The second inorganic layer 330 according to an example embodiment of the present disclosure may be disposed to cover the organic layer 320 and extend to the non-display area NDA to cover the dam DAM. At this time, the second inorganic layer 330 according to an example embodiment of the present disclosure is not formed in the pad area PA. That is, the first inorganic layer 310 and the second inorganic layer 330 according to the example embodiment of the present disclosure are formed to have ends in different locations.

In the second inorganic layer 330 according to the example embodiment of the present disclosure, in order to expose the pad electrode PAD, a mask which blocks the pad electrode PAD is disposed above the pad electrode PAD. At this time, in the display device 100 according to the example embodiment of the present disclosure, the first inorganic layer 310 is disposed on a top surface of the pad electrode PAD. Even though the mask is disposed above the pad electrode PAD, the arcing phenomenon does not occur between the boundary surface of the mask and the pad electrode PAD. That is, the first inorganic layer 310 serves as an insulating film between the mask and the pad electrode PAD. As described above, in the display device 100 according to the example embodiment of the present disclosure, the first inorganic layer 310 formed to the pad area PA serves as an insulating film. Therefore, even though during the manufacturing process of the second inorganic layer 330, the mask is disposed above the pad electrode PAD, the arcing phenomenon does not occur between the boundary surface of the mask and the pad electrode PAD.

Each of the first and second inorganic layers 310 and 330 may be formed silicon nitride, aluminum nitride, zirconium nitride, titanium nitride, hafnium nitride, tantalum nitride, silicon oxide, aluminum oxide, or titanium oxide. The organic layer 320 may be formed as acryl resin, epoxy resin, phenolic resin, polyamide resin, or polyimide resin.

The touch sensing layer 40 is formed on the encapsulation unit 30. The touch sensing layer 40 includes a buffer layer 410, a plurality of bridge electrodes BE, an insulating layer 420, a plurality of first touch electrodes TE1, a plurality of second touch electrodes TE2, and a passivation layer 430.

The buffer layer 410 is disposed on the encapsulation unit 30. The buffer layer 410 is disposed so as to cover the encapsulation layer 300. The buffer layer 410 according to the example embodiment of the present disclosure covers the encapsulation layer 300 and extends to the non-display area NDA to cover the dam DAM. Further, the buffer layer 410 according to the example embodiment of the present disclosure extends to the pad area PA disposed at the outside of the dam DAM, but exposes the pad electrode PAD without covering it. At this time, the buffer layer 410 according to the example embodiment of the present disclosure encloses the pad electrode PAD and more specifically, is disposed so as to enclose the outer periphery of the pad contact hole PCT which exposes the pad electrode PAD.

In the display device 100 according to the example embodiment of the present disclosure as described above, the buffer layer 410 extends to the pad area PA so that when the bridge electrode BE formed on the top surface of the buffer layer 410 is formed, the damage caused on the pad electrode PAD may be suppressed. To be more specific, when the bridge electrode BE is formed on the top surface of the buffer layer 410, if the pad electrode PAD is exposed, the pad electrode PAD may be damaged. In the display device 100 according to the example embodiment of the present disclosure, the buffer layer 410 is formed to the pad area PA and then the bridge electrode BE is formed so that the damage caused on the pad electrode PAD may be suppressed.

The bridge electrode BE is disposed on the buffer layer 410. In order to suppress the short circuit of the plurality of first touch electrodes TE1 and the plurality of second touch electrodes TE2 in intersections of the plurality of first touch electrodes TE1 and the plurality of second touch electrodes TE2, the bridge electrode BE electrically connects first touch electrodes TE1 which are adjacent to each other in the first direction. The bridge electrode BE is disposed on a different layer from the first and second touch electrodes TE1 and TE2 and may be connected to the first touch electrodes TE1 which are adjacent to each other through the bridge contact holes BCT. The bridge electrode BE may intersect the second touch electrode TE2.

The insulating layer 420 is disposed on the bridge electrode BE. The insulating layer 420 is disposed so as to cover the bridge electrode BE to insulate the bridge electrode BE and the first and second touch electrodes TE1 and TE2. The insulating layer 420 according to the example embodiment of the present disclosure covers the bridge electrode BE and extends to the non-display area NDA to be formed to the pad area PA. The insulating layer 420 according to the example embodiment of the present disclosure extends to the pad area PA disposed at the outside of the dam DAM, but exposes the pad electrode PAD without covering it. At this time, the insulating layer 420 according to the example embodiment of the present disclosure encloses the pad electrode PAD and more specifically, is disposed so as to enclose the outer periphery of the pad contact hole PCT which exposes the pad electrode PAD.

In the display device 100 according to the example embodiment of the present disclosure as described above, the insulating layer 420 extends to the pad area PA so that in order not to form the insulating layer 420 in the pad area PA, a mask which blocks the pad electrode PAD does not need to be disposed above the pad electrode PAD.

The buffer layer 410 and the insulating layer 420 disposed on a top surface of the pad electrode PAD may be simultaneously removed to expose the pad electrode PAD during the process of forming the bridge contact hole BCT. That is, the bridge contact hole BCT and the pad contact hole PCT may be simultaneously formed.

Referring to FIGS. 5 and 6, the plurality of first touch electrodes TE1 and the plurality of second touch electrodes TE2 are disposed on the insulating layer 420. The plurality of first touch electrodes TE1, the plurality of second touch electrodes TE2, the plurality of first touch lines TL1, and the plurality of second touch lines TL2 may be disposed on the same layer. The first touch electrodes TE1 are disposed in a first direction (an x axis direction or a y axis direction) to be connected to each other and the second touch electrodes TE2 is disposed in a second direction (the y axis direction or the x axis direction) to be connected to each other. The first direction is parallel to scan lines S1 to Sn and the second direction may be parallel to the data lines D1 to Dm. Alternatively, the first direction is parallel to data lines D1 to Dm and the second direction may be parallel to the scan lines S1 to Sn.

Each of the first touch electrodes TE1 connected in the first direction is electrically insulated from the first touch electrode TE1 adjacent in the second direction. Each of the second touch electrodes TE2 connected in the second direction is electrically insulated from the second touch electrode TE2 adjacent in first direction.

By doing this, mutual capacitance corresponding to the touch sensor may be formed in the intersecting area of the first touch electrode TE1 and the second touch electrode TE2.

A first touch electrode TE1 disposed at one side, among the first touch electrodes TE1 connected to each other in the first direction may be connected to the first touch line TL1 in the non-display area NDA. The first touch line TL1 extends to the first touch electrode TE1 to form a pattern to the pad area PA. The first touch line TL1 is connected to the pad electrode PAD in the pad area PA to be connected to the first touch driver 181 through the pad electrode PAD. Accordingly, the first touch electrodes TE1 connected to each other in the first direction may receive a driving pulse from the first touch driver 181 through the first touch line TL1.

A second touch electrode TE2 disposed at one side, among the second touch electrodes TE2 connected to each other in the second direction may be connected to the second touch line TL2 in the non-display area NDA. The second touch line TL2 extends to the second touch electrode TE2 to form a pattern to the pad area PA. The second touch line TL2 is connected to the pad electrode PAD in the pad area PA to be connected to the second touch driver 182 through the pad electrode PAD. Accordingly, the second touch driver 182 receives charge variances of the touch sensors of the second touch electrodes TE2 which are connected to each other in the second direction.

The passivation layer 430 is disposed on the first touch electrode TE1 and the second touch electrode TE2. The passivation layer 430 blocks harmful substances from the outside to maintain stability of the characteristic of the display device. Further, the passivation layer 430 may be disposed not only on the first touch electrodes TE1 and the second touch electrodes TE2, but also between the first touch electrodes TE1 and the second touch electrodes TE2. The first touch electrodes TE1 may be insulated from each of the second touch electrodes TE2 by the passivation layer 430.

According to the example embodiment of the present disclosure, the touch sensing layer 40 is directly formed on the encapsulation unit 30 so that when the first substrate 111 and the second substrate 112 are bonded, alignment is not necessary.

As described above, in the display device 100 according to the example embodiment of the present disclosure, the first inorganic layer 310 is formed to extend to the pad area PA so that a mask which blocks the pad electrode PAD does not need to be disposed above the pad electrode PAD.

Accordingly, in the display device 100 according to the example embodiment of the present disclosure, the mask is not disposed above the pad electrode PAD so that arcing phenomenon caused between a boundary surface of the mask and the pad electrode may be suppressed. Further, the high current which flows from the mask may be suppressed from flowing into the display device 100 along the pad electrode PAD to cause the defects.

In the meantime, in the display device 100 according to the example embodiment of the present disclosure, a light reinforcement layer is formed between the plurality of sub pixels SP to reduce reflection of external light and improve a light extraction efficiency. Hereinafter, a light reinforcement layer of a display device 100 according to an example embodiment of the present disclosure will be described in detail with reference to FIGS. 7 to 11.

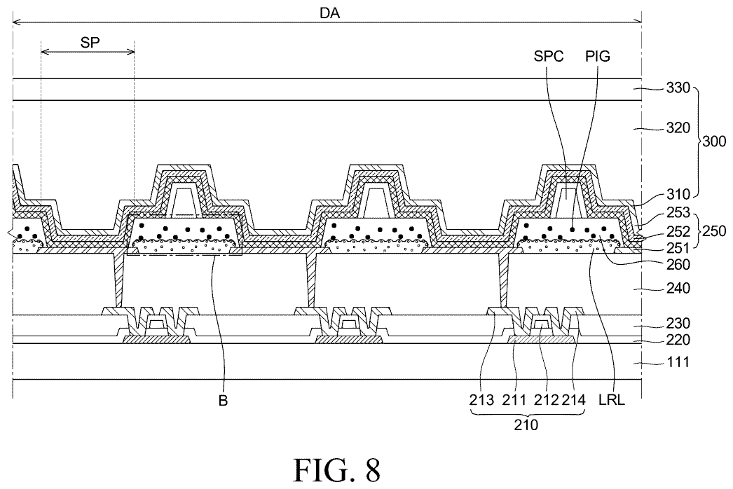

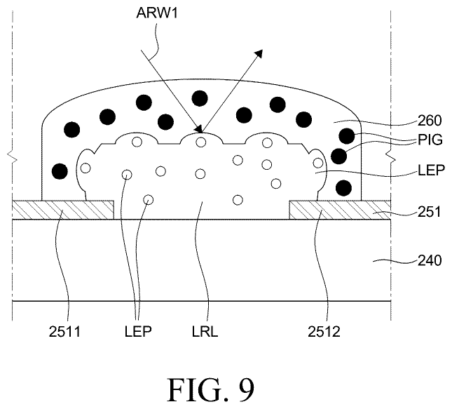

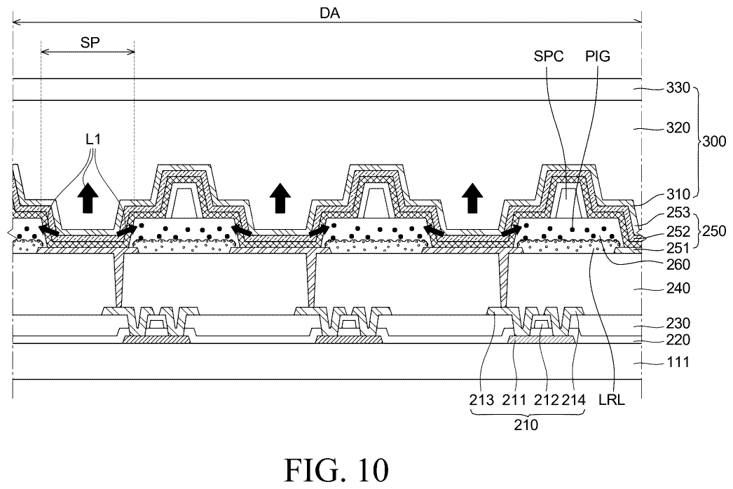

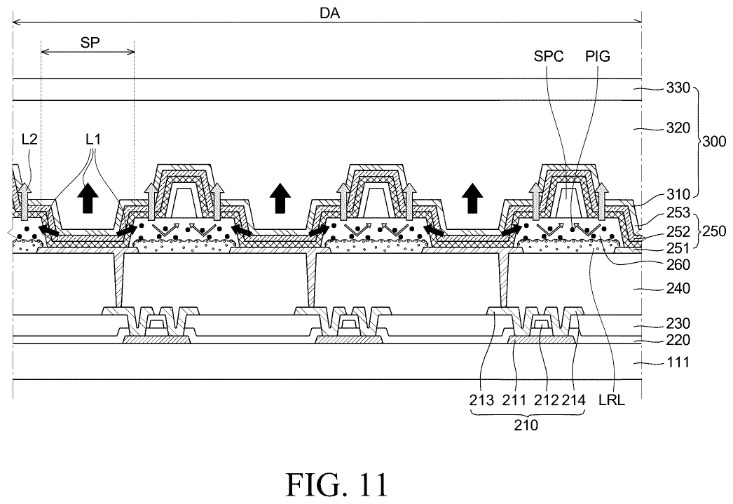

FIG. 7 is a schematic enlarged plan view of an active area of a display device according to an example embodiment of the present disclosure. FIG. 8 is a cross-sectional view taken along line A-A′ of FIG. 7. FIG. 9 is a cross-sectional view of an area B of FIG. 8 according to an example embodiment of the present disclosure. FIG. 10 is a cross-sectional view for explaining an example of generating primary light of a display device according to an example embodiment of the present disclosure. FIG. 11 is a cross-sectional view for explaining an example that secondary light of a display device according to an example embodiment of the present disclosure is generated and is blocked by a light reinforcement layer. Specifically, FIG. 7 is an enlarged plan view of a display area DA of the display device of FIG. 4 and schematically illustrates a front surface of a pixel P configured by a plurality of sub pixels SP. FIG. 8 illustrates a cross-section of the display device taken along line A-A′ of FIG. 7 and FIG. 9 schematically illustrates a cross-section of a part including a light reinforcement layer according to an example embodiment of the present disclosure in the area B of FIG. 8. FIG. 10 illustrates an example of generating primary light and FIG. 11 illustrates an example of generating secondary light and blocking the light by the light reinforcement layer.

Referring to FIGS. 7 to 9, the display device 100 according to the example embodiment of the present disclosure may include a plurality of sub pixels SP and a light reinforcement layer LRL disposed between the plurality of sub pixels SP. The light reinforcement layer LRL may be disposed between different sub pixels SP. For example, the light reinforcement layer LRL may be disposed between the first sub pixel SP1 and the second sub pixel SP2 which are adjacent to each other.

The light reinforcement layer LRL may be disposed on a planarization layer 240. In the display device 100 according to the example embodiment of the present disclosure, the light reinforcement layer LRL is disposed on the planarization layer 240 while covering edges of a first electrode 251. For example, the first electrode 251 may be an anode electrode of the light emitting diode 250. Therefore, the light reinforcement layer LRL may have a non-conductive property and include a resin having an insulating property. Referring to FIGS. 9 and 10, the light reinforcement layer LRL covers the edge of the first electrode 251 to minimize the external light entering into the display device 100 and the loss of the primary light L1. For reference, when the light reinforcement layer LRL does not cover an area between the first electrodes 251, an external light may enter into the display device 100 through the space between the first electrodes 251.

In one example, the light reinforcement layer LRL may be disposed between the first electrode 251 which are adjacent to each other. The adjacent first electrodes 251 includes a first electrode unit 2511 which configures the first sub pixel SP1 and a second electrode unit 2512 which configures the second sub pixel SP2. The first sub pixel SP1 and the second sub pixel SP2 may be disposed to be adjacent to each other. The first sub pixel SP1 and the second sub pixel SP2 may be configured to represent different colors.

The light reinforcement layer LRL may include a plurality of scattering particles LEP. The plurality of scattering particles LEP may be dispersed into the light reinforcement layer LRL. The plurality of scattering particles LEP in the light reinforcement layer LRL may scatter light which is incident to the light reinforcement layer LRL. The scattering particles LEP may include TiO₂, a PMMA based polymer, hollow silica, ZnO or Al₂O₃ or may be configured by them. An optical path ARW1 of light which is incident toward the light reinforcement layer LRL may increase by the scattering particles LEP. The increasing optical path ARW1 may increase light absorbance of optical materials PIG contained in the bank 260.

The thickness of the first electrode 251 may be smaller than a thickness of the light reinforcement layer LRL. For example, the thickness of the light reinforcement layer LRL may be 0.1 to 1 μm and a thickness of the first electrode 251 may be 0.1 μm or smaller.

Referring to FIGS. 7, 8, and 9, the display device 100 according to the example embodiment of the present disclosure includes a first substrate 111. The first substrate 111 may include a display area DA and a non-display area NDA. In the display area DA, a plurality of pixels P each including a plurality of sub pixels SP may be disposed. The display area DA may display image information through the plurality of sub pixels SP. The non-display area NDA does not display image information, but a circuit design or an electronic component for driving the display device 100 may be disposed therein.

The light emitting diode 250 of the display device 100 according to the example embodiment of the present disclosure includes a first electrode 251, a second electrode 253, and a light emitting layer 252. The first electrode 251, the light emitting layer 252, and the second electrode 253 may configure the light emitting diode 250. The light emitting diode 250 may make light using a voltage difference between the first electrode 251 and the second electrode 253. Specifically, the light emitting layer 252 generates light with a predetermined wavelength based on the voltage difference between the first electrode 251 and the second electrode 253. The light emitting diode 250 may include a white light emitting diode, a red light emitting diode, a blue light emitting diode, or a green light emitting diode, but the example embodiments of the present disclosure are not limited thereto. Further, each light emitting diode 250 may be defined as one sub pixel SP. The sub pixel SP may include a white sub pixel, a red sub pixel, a blue sub pixel, or a green sub pixel, but the example embodiments of the present disclosure are not limited thereto.

The first electrode 251 may be disposed on the planarization layer 240. The first electrode 251 is disposed on the planarization layer 240 and is electrically connected to the thin film transistor 210 through a contact hole of the planarization layer 240. Emission of the light emitting diode 250 may be controlled by the thin film transistor 210 which is electrically connected to the first electrode 251.

The second electrode 253 may be disposed on the light emitting layer 252. Alternatively, the second electrode 253 may be disposed on the light emitting layer 252 and the bank 260. Light generated by the light emitting layer 252 passes through the second electrode 253 to be perceived by the human naked eye.

A spacer SPC is disposed between the bank 260 and the light emitting layer 252. During the process of forming the light emitting layer 252, the spacer SPC maintains a constant distance between the mask and the bank 260 and may suppress defects due to the contact of the mask and the bank 260. For example, the spacer SPC may be formed of an organic film, such as acryl resin, epoxy resin, phenolic resin, polyamide resin, or polyimide resin.

For reference, the light emitting layer 252 illustrated in FIG. 8 is mainly disposed between the banks 260. In one example, the light emitting layer 252 may also be disposed on the first electrode 251 on the bank 260, the light emitting layer 252 for implementing a light generating function of the light emitting diode 250 is actually disposed between the banks 260 and may be disposed between the banks 260. Therefore, in one example, the light emitting layer 252 is disposed only between the banks 260, but may not be disposed on the bank 260 or the spacer SPC.

The display device 100 according to the example embodiment of the present disclosure includes a bank 260. The bank 260 may be disposed between the light emitting diodes 250. The bank 260 is disposed between the light emitting diodes 250 and may distinguish the adjacent light emitting diodes 250. The bank 260 covers an end of the first electrode 251 and may cover the light reinforcement layer LRL. The bank 260 may contain a black material which easily absorbs light. The bank 260 containing the black material is disposed between the light emitting diodes 250 and may spatially separate light generated from the adjacent light emitting diodes 250. The light emitting diodes 250 of different colors are separated by the bank 260 and may be distinguished by the user.

The bank 260 may contain an optical material PIG configured to emit secondary light L2 by absorbing primary light L1. The primary light L1 refers to light generated from the light emitting diode 250. The secondary light L2 refers to light generated by the optical material PIG of the bank 260. The secondary light L2 is light emitted from the optical material PIG of the bank 260 by absorbing the primary light L1. The primary light L1 may be light in a visible ray band. The secondary light L2 may be light in a non-visible ray band. For example, the secondary light L2 may be light in infrared ray or near-infrared ray band. The optical material PIG contained in the bank 260 may absorb the primary light L1 at a high efficiency to output light in the non-visible ray band.

The optical material PIG may be a quantum dot or a quantum rod. For the convenience of description, it is described as a quantum dot, but the quantum dot may be used interchangeably with the quantum rod. The quantum dot may refer to nano particles which emits light by photoluminescence (PL) in which electrons excited by external light move down from a conduction band to a valence band to emit light or electroluminescence (EL) in which light is emitted by external charges.

The quantum dot may include a first semiconductor nano crystal which absorbs primary light L1 in the visible ray band range. That is, the first semiconductor nano crystal may include a group III-V compound. In the present disclosure, “Group” refers to the group of the periodic table of elements. The group III-V compound may be boron phosphide (BP), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), aluminum nitride (AlN), or boron nitride (BN). For example, the first semiconductor nano crystal may include indium (In) and/or arsenic (As).

The primary light L1 having a wavelength in the visible ray band range may be absorbed by the quantum dot. As the quantum dots absorb the primary light L1 in the visible ray band range, the bank 260 may lower the reflectance of the display device.

The particle size of the quantum dot is not specifically limited. The particle size of the quantum dot may be selected within a particle size which allows the quantum dot to have a high light absorbance to the primary light L1 having a wavelength in the visible ray band range to allow the display device 100 to have a low reflectance.

The quantum dot may include a second semiconductor nano crystal which emits secondary light L2 in the infrared ray or near-infrared ray band range. When the quantum dot includes a second semiconductor nano crystal which emits secondary light L2 in the infrared ray or near-infrared ray band range, the bank 260 emits infrared ray and the display device 100 may further include various optical electronic devices which use emitted infrared ray.

The second semiconductor nano crystal may include a group II-VI compound. The group II-VI compound may be, for example, lead sulfide (PbS), lead selenide (PbSe), magnesium sulfide (MgS), magnesium selenide (MgSe), magnesium telluride (MgTe), calcium sulfide (CaS), calcium selenide (CaSe), calcium telluride (CaTe), strontium sulfide (SrS), strontium selenide (SrSe), strontium telluride (SrTe), cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), or mercury telluride (HgTe).

The second semiconductor nano crystal may include zinc (Zn) and/or selenium (Se).

As the quantum dot includes the above-described second semiconductor nano crystal, the quantum dot emits light in the infrared ray band range and an electronic device using the infrared ray which may be included in the display device 100 may apply the infrared ray.

Hereinafter, a process of generating primary light and secondary light and blocking the secondary light by a light reinforcement layer will be described in detail with reference to FIGS. 10 and 11.

Referring to FIGS. 10 and 11, the light emitting diode 250 may generate primary light L1. The primary light L1 may propagate toward a front surface, a side surface, and a rear surface of the display device. The primary light L1 directed to the front surface may travel to the external. The primary light L1 directed to the rear surface is reflected by the first electrode 251 to travel to the external. A part of the primary light L1 directed to the side surface may be absorbed by the optical material PIG of the bank 260.

When the optical material of the bank 260 absorbs the primary light L1, the optical material may generate secondary light L2. The secondary light L2 is light in the non-visible ray band. For example, the secondary light L2 has a wavelength in the infrared ray or near-infrared ray band and is not discerned by the user's naked eye. The secondary light L2 propagates toward a front surface, a side surface, and a rear surface of the bank 260.

The display device 100 according to the example embodiment of the present disclosure may include a light reinforcement layer LRL. The light reinforcement layer LRL may be disposed below the bank 260. The light reinforcement layer LRL disposed below the bank 260 may scatter the external light which is incident onto the bank 260 to prevent the external light from arriving at the circuit elements in the display device 100. By providing the light reinforcement layer LRL, the external light is prevented from passing through the space between the first electrodes 251 to arrive at the circuit elements, and thus external light reflection caused by the circuit elements may be prevented. Further, the light reinforcement layer LRL disposed below the bank 260 may scatter the primary light L1 and the secondary light L2, so that a part of the primary light L1 and a part of the secondary light L2 are reflected toward the front surface.

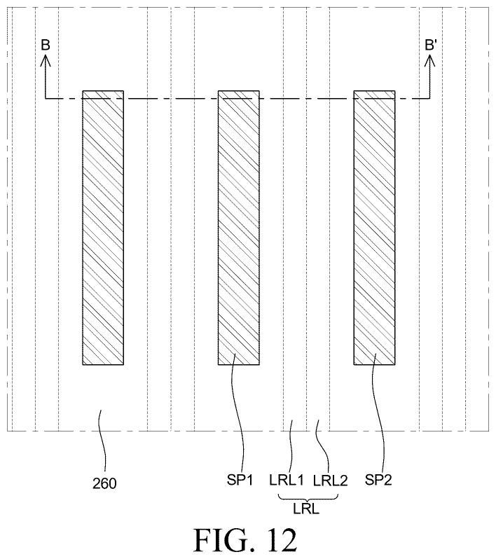

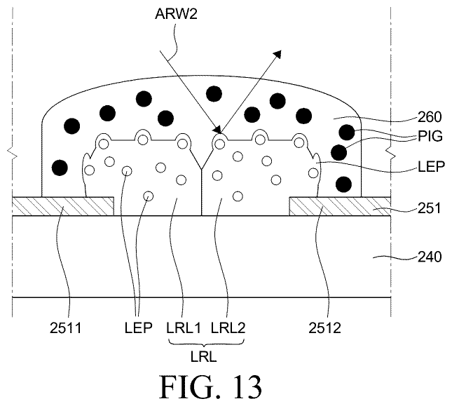

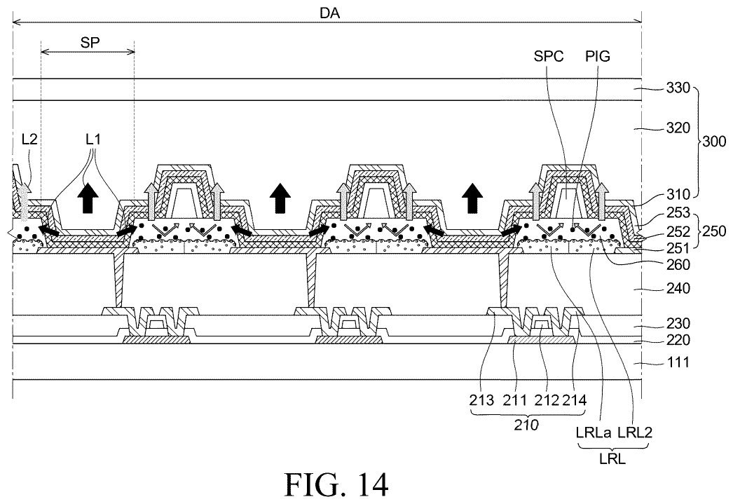

FIG. 12 is a schematic enlarged plan view of a display device according to another example embodiment of the present disclosure. FIG. 13 is a schematic cross-sectional view of the light reinforcement layer of a display device according to another example embodiment of the present disclosure. FIG. 14 is a cross-sectional view taken along line B-B′ of FIG. 12. Specifically, FIG. 12 schematically illustrates a front surface of a display device according to another example embodiment of the present disclosure. FIG. 13 schematically illustrates a cross-section for the light reinforcement layer LRL according to another example embodiment of the present disclosure. FIG. 14 schematically illustrates a cross-section taken along line B-B′ of the display device of FIG. 12. Only the light reinforcement layer LRL of the display device of FIGS. 12 to 14 is different from that of the display device of FIGS. 1 to 11, the other configuration is substantially the same so that a redundant description will be omitted.

Referring to FIG. 12, the display device according to another example embodiment of the present disclosure may include a plurality of sub pixels SP1 and SP2 and a light reinforcement layer LRL disposed between the plurality of sub pixels SP1 and SP2. The light reinforcement layer LRL may be disposed between different sub pixels. For example, the light reinforcement layer LRL may be disposed between the first sub pixel SP1 and the second sub pixel SP2 which are adjacent to each other.

In the display device according to another example embodiment of the present disclosure, the light reinforcement layer LRL may include a first light reinforcement layer LRL1 and a second light reinforcement layer LRL2. The first light reinforcement layer LRL1 may be disposed to be adjacent to the first sub pixel SP1. The second light reinforcement layer LRL2 may be disposed to be adjacent to the second sub pixel SP2. The first light reinforcement layer LRL1 and the second light reinforcement layer LRL2 may be disposed to be adjacent to each other.

Referring to FIGS. 12 and 13, the light reinforcement layer LRL may be disposed on the planarization layer 240. In the display device according to another example embodiment of the present disclosure, the light reinforcement layer LRL may be disposed on the planarization layer 240 while covering edges of the first electrode 251. The first electrode 251 may serve as an anode electrode of the light emitting diode 250. Therefore, the light reinforcement layer LRL covers the anode but may be non-conductive. The light reinforcement layer LRL covers the edge of the first electrode 251 to minimize the external light entering into the display device 100 and the loss of the primary light L1. For reference, when the light reinforcement layer LRL does not cover the first electrode 251, the external light may permeate below the first electrode 251.

In one example, the light reinforcement layer LRL may be disposed between the first electrode 250 which are adjacent to each other. The adjacent first electrodes 251 may include a first electrode unit 2511 which configures the first sub pixel SP1 and a second electrode unit 2512 which configures the second sub pixel SP2. The first sub pixel SP1 and the second sub pixel SP2 may be disposed to be adjacent to each other. The first sub pixel SP1 and the second sub pixel SP2 may be configured to represent different colors.

Specifically, the light reinforcement layer LRL may include a first light reinforcement layer LRL1 and a second light reinforcement layer LRL2 and the first light reinforcement layer LRL1 is disposed on the first electrode unit 2511 and the second light reinforcement layer LRL2 may be disposed on the second electrode unit 2512. A part of the first light reinforcement layer LRL1 covers the edge of the first electrode unit 2511 and the remaining part may be disposed on the planarization layer 240. A part of the second light reinforcement layer LRL2 covers the edge of the second electrode unit 2512 and the remaining part may be disposed on the planarization layer 240.

In the display device according to another example embodiment of the present disclosure, the first light reinforcement layer LRL1 and the second light reinforcement layer LRL2 may be disposed to be in contact with each other. As the first light reinforcement layer LRL1 and the second light reinforcement layer LRL2 are in contact with each other, an empty space is not formed between the first light reinforcement layer LRL1 and the second light reinforcement layer LRL2. A groove having a predetermined depth may be formed between the first light reinforcement layer LRL1 and the second light reinforcement layer LRL2.

Further, the light reinforcement layer LRL may include a plurality of scattering particles LEP. The plurality of scattering particles LEP may be dispersed into the light reinforcement layer LRL. The plurality of scattering particles LEP in the light reinforcement layer LRL may scatter light which is incident to the light reinforcement layer LRL. The scattering particles LEP may include TiO₂, a PMMA based polymer, hollow silica, ZnO or Al₂O₃ or may be configured by them. An optical path ARW2 of light which is incident toward the light reinforcement layer LRL may increase by the scattering particles LEP. The increasing optical path ARW2 may increase light absorbance of optical materials PIG contained in the bank 260.

The thickness of the first electrode 251 may be smaller than a thickness of the light reinforcement layer LRL. For example, the thickness of the light reinforcement layer LRL may be 0.1 to 1 μm and a thickness of the first electrode 251 may be 0.1 μm or smaller.

Referring to FIGS. 12, 13, and 14, the display device according to another example embodiment of the present disclosure may include a plurality of light reinforcement layers LRL. The plurality of light reinforcement layers LRL may include a first light reinforcement layer LRL1 and a second light reinforcement layer LRL2. The first light reinforcement layer LRL1 and the second light reinforcement layer LRL2 may be disposed below the bank 260. Below the bank 260, the first light reinforcement layer LRL1 and the second light reinforcement layer LRL2 block light (including primary light L1 and secondary light L2) which propagates to a space between adjacent first electrodes 251.

Forming the first light reinforcement layer LRL1 and the second light reinforcement layer LRL2 in the display device may suppress the reduction in a process yield compared with the case where the light reinforcement layer LRL is not formed, in advance. Therefore, the productivity of the display device may be improved.

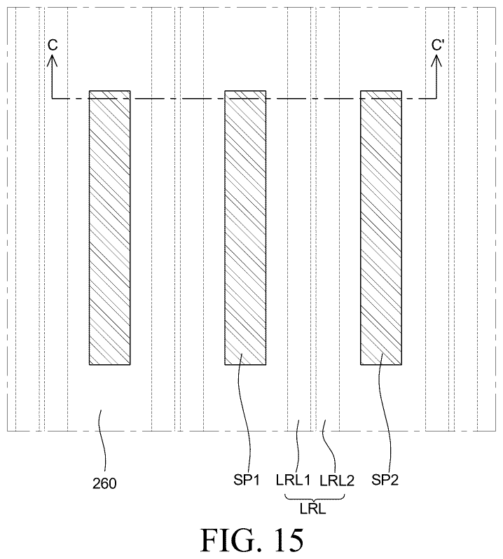

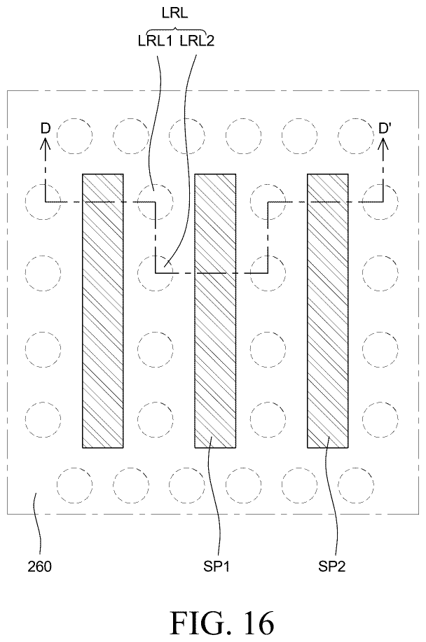

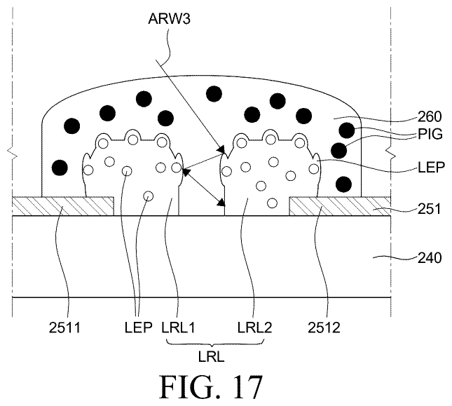

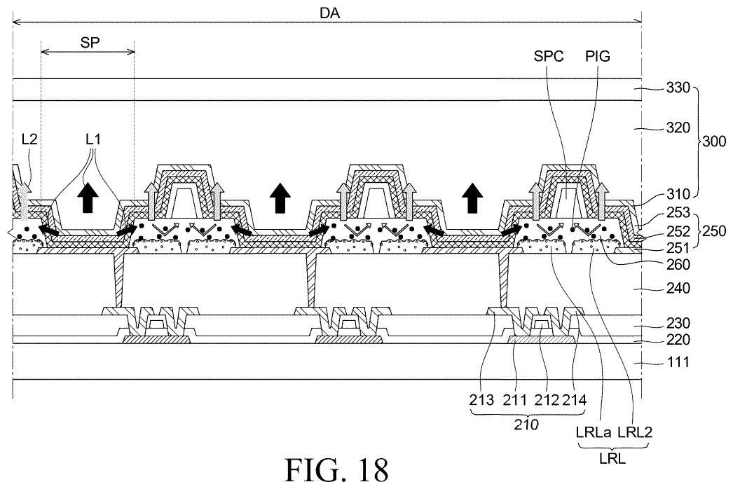

FIGS. 15 and 16 are schematic enlarged plan views of a display device according to still another example embodiment of the present disclosure. FIG. 17 is a schematic cross-sectional view of a light reinforcement layer of a display device according to still another example embodiment of the present disclosure. FIG. 18 is a cross-sectional view which is commonly applicable to a cross-section taken along line C-C′ of FIG. 15 and a cross-section taken along line D-D′ of FIG. 16. Specifically, FIGS. 15 and 16 schematically illustrate a front surface of a display device according to still another example embodiment of the present disclosure. FIG. 17 schematically illustrates a cross-section for the light reinforcement layer LRL according to still another example embodiment of the present disclosure. FIG. 18 schematically illustrates a cross-section of the display device taken along line C-C′ of FIG. 15 and a cross-section of the display device taken along line D-D′ of FIG. 16. Only the light reinforcement layer LRL of the display device of FIGS. 15 to 18 is different from that of the display device of FIGS. 1 to 11, the other configuration is substantially the same so that a redundant description will be omitted.

Referring to FIGS. 15 and 16, the display device according to still another example embodiment of the present disclosure may include a plurality of sub pixels SP1 and SP2 and a light reinforcement layer LRL disposed between the plurality of sub pixels SP1 and SP2. The light reinforcement layer LRL may be disposed between different sub pixels. For example, the light reinforcement layer LRL may be disposed between the first sub pixel SP1 and the second sub pixel SP2 which are adjacent to each other.

In the display device according to still another example embodiment of the present disclosure, the light reinforcement layer LRL may include a first light reinforcement layer LRL1 and a second light reinforcement layer LRL2. The first light reinforcement layer LRL1 may be disposed to be adjacent to the first sub pixel SP1. The second light reinforcement layer LRL2 may be disposed to be adjacent to the second sub pixel SP2. The first light reinforcement layer LRL1 and the second light reinforcement layer LRL2 may be disposed to be adjacent to each other.

In the display device according to still another example embodiment of the present disclosure, the first light reinforcement layer LRL1 and the second light reinforcement layer LRL2 may be spaced apart from each other. A space with a predetermined width may be formed between the first light reinforcement layer LRL1 and the second light reinforcement layer LRL2. For example, the width of the space may be 1 μm or larger. Within the space, light reflection by the first light reinforcement layer LRL1 and the second light reinforcement layer LRL2 may be caused. Therefore, the optical path of light (including primary light L1 and secondary light L2) propagating in the space may be increased. The light absorption rate by the optical material PIG contained in the bank 260 may be increased in proportion to the increasing optical path.

Referring to FIGS. 15 to 17, the space between the first light reinforcement layer LRL1 and the second light reinforcement layer LRL2 may be formed in various manners. For example, referring to FIG. 15, the space may be formed between the first light reinforcement layer LRL1 and the second light reinforcement layer LRL2 which are spaced apart from each other to be linearly disposed. As another example, referring to FIG. 16, the space may be formed between the first light reinforcement layer LRL1 and the second light reinforcement layer LRL2 which are spaced apart from each other to be circularly disposed. In various example embodiments of the present disclosure, the first light reinforcement layer LRL1 and the second light reinforcement layer LRL2 are used to discern the light reinforcement layers LRL which are spaced apart from each other and the display device may include more than two light reinforcement layers LRL.

Referring to FIGS. 15 to 18, the light reinforcement layer LRL may be disposed on the planarization layer 240. In the display device according to still another example embodiment of the present disclosure, the light reinforcement layer LRL is disposed on the planarization layer 240 while covering edges of the first electrode 251. The first electrode 251 may serve as an anode electrode of the light emitting diode 250. Therefore, the light reinforcement layer LRL covers the anode but may be non-conductive. The light reinforcement layer LRL covers the edge of the first electrode 251 to minimize the external light entering into the display device 100 and the loss of the primary light L1. For reference, when the light reinforcement layer LRL does not cover the first electrode 251, the external light may permeate below the first electrode 251.

In one example, the light reinforcement layer LRL may be disposed between the first electrode 250 which are adjacent to each other. The adjacent first electrodes 251 may include a first electrode unit 2511 which configures the first sub pixel SP1 and a second electrode unit 2512 which configures the second sub pixel SP2. The first sub pixel SP1 and the second sub pixel SP2 may be disposed to be adjacent to each other. The first sub pixel SP1 and the second sub pixel SP2 may be configured to represent different colors.

Specifically, the light reinforcement layer LRL may include a first light reinforcement layer LRL1 and a second light reinforcement layer LRL2 and the first light reinforcement layer LRL1 is disposed on the first electrode unit 2511 and the second light reinforcement layer LRL2 may be disposed on the second electrode unit 2512. A part of the first light reinforcement layer LRL1 covers the edge of the first electrode unit 2511 and the remaining part may be disposed on the planarization layer 240. A part of the second light reinforcement layer LRL2 covers the edge of the second electrode unit 2512 and the remaining part may be disposed on the planarization layer 240.

In the display device according to still another example embodiment of the present disclosure, the first light reinforcement layer LRL1 and the second light reinforcement layer LRL2 may be spaced apart from each other. The bank 260 may be disposed while being filled between the first light reinforcement layer LRL1 and the second light reinforcement layer LRL2. Specifically, the bank 260 may be disposed to be filled in a space between the first light reinforcement layer LRL1 and the second light reinforcement layer LRL2.

Further, the light reinforcement layer LRL may include a plurality of scattering particles LEP. The plurality of scattering particles LEP may be dispersed into the light reinforcement layer LRL. The plurality of scattering particles LEP in the light reinforcement layer LRL may scatter light which is incident to the light reinforcement layer LRL. The scattering particles LEP may include TiO₂, a PMMA based polymer, hollow silica, ZnO or Al₂O₃ or may be configured by them. An optical path ARW3 of light which is incident toward the light reinforcement layer LRL may increase by the scattering particles LEP. The increasing optical path ARW3 may increase light absorbance of optical materials PIG contained in the bank 260.

The thickness of the first electrode 251 is smaller than a thickness of the light reinforcement layer LRL. For example, the thickness of the light reinforcement layer LRL may be 0.1 to 1 μm and a thickness of the first electrode 251 may be 0.1 μm or smaller.

Referring to FIGS. 15 to 18, the display device according to another example embodiment of the present disclosure may include a plurality of light reinforcement layers LRL. The plurality of light reinforcement layers LRL may include a first light reinforcement layer LRL1 and a second light reinforcement layer LRL2. The first light reinforcement layer LRL1 and the second light reinforcement layer LRL2 may be disposed below the bank 260. Below the bank 260, the first light reinforcement layer LRL1 and the second light reinforcement layer LRL2 may block light (including primary light L1 and secondary light L2) which propagates to a space between adjacent first electrodes 251.

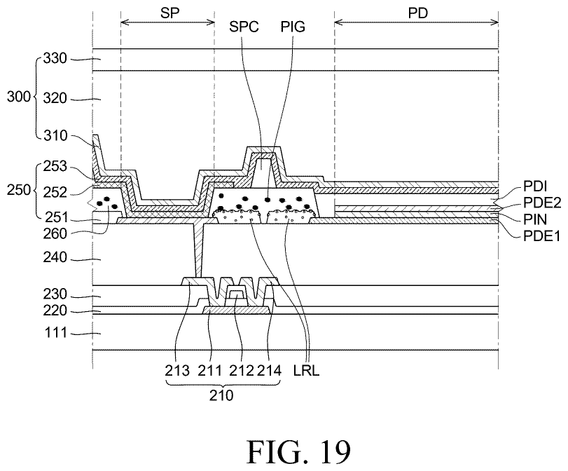

FIG. 19 schematically illustrates a cross-section of a display device including a photo diode according to still another example embodiment of the present disclosure. Specifically, the display device of FIG. 19 has the substantially same configuration as the display device of FIGS. 15 to 18 except that a photo diode PD is further included so that a redundant description will be omitted.

Referring to FIG. 19, the display device may include a photo diode PD. The photo diode PD may be located above the first substrate 111. The photo diode PD may be disposed above the planarization layer 24. When the photo diode PD is located below the light reinforcement layer LRL, light (for example, including secondary light L2) is blocked by the light reinforcement layer LRL. Therefore, the photo diode PD may be disposed above or parallel to the light reinforcement layer LRL. In an example embodiment of the present disclosure, the photo diode PD may be preferably disposed above the planarization layer 24.

The photo diode PD may be a photo diode PD which detects light with a wavelength in an infrared or near-infrared band range. The display device includes a photo diode PD to recognize that an object approaches using the photo diode PD. Therefore, when the secondary light L2 generated in the bank 260 is reflected by a reflector, the reflected secondary light L2 may reach the photo diode PD. Therefore, the bank 260 containing an optical material PIG may be applied to a proximity sensor using infrared ray.

The photo diode PD may include a first photo diode electrode PDE1, a semiconductor layer PIN, and a second photo diode electrode PDE2. The first photo diode electrode PDE1 may be disposed on the planarization layer 240. The semiconductor layer PIN and the second photo diode electrode PDE2 may be sequentially disposed on the first photo diode electrode PDE1.

The first photo diode electrode PDE1 may be formed of the substantially same material as the first electrode 251, but is not limited thereto.

The photo diode PD may further include an intermediate insulating layer PDI. The intermediate insulating layer PDI may be disposed on the second photo diode electrode PDE2. The second electrode 253 may be disposed above the photo diode PD. The second electrode 253 may be electrically separated from the second photo diode electrode PDE2 by the intermediate insulating layer PDI.

The example embodiments of the present disclosure can also be described as follows:

According to an aspect of the present disclosure, a display device includes a substrate, a planarization layer disposed on the substrate, a first electrode disposed on the planarization layer, a light reinforcement layer disposed on the first electrode and the planarization layer, a bank which is disposed on the light reinforcement layer and includes an optical material, a light emitting layer disposed on the first electrode, and a second electrode disposed on the light emitting layer and the bank, and the light reinforcement layer is disposed so as to cover at least a part of the first electrode.

The light reinforcement layer may be disposed between first electrodes which are adjacent to each other.

The light reinforcement layer may be disposed while covering edges of the first electrodes which are adjacent to each other.

The first electrodes which are adjacent to each other may include a first electrode unit which configures a first sub pixel and a second electrode unit which configures a second sub pixel adjacent to the first sub pixel, and the light reinforcement layer may include a first light reinforcement layer disposed on the first electrode unit and a second light reinforcement layer disposed on the second electrode unit.

The first light reinforcement layer and the second light reinforcement layer may be spaced apart from each other.

The bank may be disposed while being filled between the first light reinforcement layer and the second light reinforcement layer.

The first light reinforcement layer and the second light reinforcement layer may be in contact with each other.

The light reinforcement layer may be non-conductive.

The light reinforcement layer may include a plurality of scattering particles.

The plurality of scattering particles may be disposed on a front surface of the light reinforcement layer.

The light reinforcement layer may be configured to diffuse or reflect the incident light.

The display device may further include a photo diode disposed on the planarization layer.

The optical material may be configured to absorb primary light to emit secondary light.

The primary light may be visible ray and the secondary light may be infrared light.

The optical material may include a plurality of nano particles.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The scope of protection of the present disclosure should be construed based on the following claims, and all technical features within the scope of equivalents thereof should be construed as being included within the scope of the present disclosure.

What is claimed is:

1. A display device, comprising:
a substrate;
a planarization layer disposed on the substrate;
a first electrode disposed on the planarization layer;
a light reinforcement layer disposed on the planarization layer;
a bank disposed on the light reinforcement layer and includes an optical material;
a light emitting layer disposed on the first electrode; and
a second electrode disposed on the light emitting layer and the bank,
wherein the light reinforcement layer is disposed so as to cover at least a part of the first electrode.

2. The display device according to claim 1, wherein the light reinforcement layer is disposed between first electrodes which are adjacent to each other.

3. The display device according to claim 2, wherein the light reinforcement layer is disposed while covering edges of the first electrodes which are adjacent to each other.

4. The display device according to claim 2, wherein the first electrodes which are adjacent to each other include a first electrode unit which configures a first sub pixel and a second electrode unit which configures a second sub pixel adjacent to the first sub pixel; and
the light reinforcement layer includes a first light reinforcement layer disposed on the first electrode unit and a second light reinforcement layer disposed on the second electrode unit.

5. The display device according to claim 4, wherein the first light reinforcement layer and the second light reinforcement layer are spaced apart from each other.

6. The display device according to claim 5, wherein the bank is disposed while being filled between the first light reinforcement layer and the second light reinforcement layer.

7. The display device according to claim 4, wherein the first light reinforcement layer and the second light reinforcement layer are in contact with each other.

8. The display device according to claim 1, wherein the light reinforcement layer is non-conductive.

9. The display device according to claim 1, wherein the light reinforcement layer includes a plurality of scattering particles.

10. The display device according to claim 9, wherein the plurality of scattering particles are disposed on a front surface of the light reinforcement layer.

11. The display device according to claim 1, wherein the light reinforcement layer is configured to diffuse or reflect incident light.

12. The display device according to claim 1, further comprising:
a photo diode disposed on the planarization layer.

13. The display device according to claim 1, wherein the optical material is configured to absorb primary light to emit secondary light.

14. The display device according to claim 13, wherein the primary light is visible ray and the secondary light is infrared light.

15. The display device according to claim 13, wherein the optical material includes a plurality of nano particles.

16. A display device, comprising:
a substrate;
a first electrode disposed on the substrate;
a light reinforcement layer disposed on a planarization layer;
a bank disposed on the substrate and covering an edge of the first electrode;
a light emitting layer disposed on the first electrode; and
a second electrode disposed on the light emitting layer.

17. The display device according to claim 16, wherein the bank includes a plurality of nano particles.

18. The display device according to claim 16, wherein the light reinforcement layer includes a plurality of scattering particles.

19. The display device according to claim 18, wherein the plurality of scattering particles include TiO₂, a PMMA based polymer, hollow silica, ZnO or Al₂O₃.

20. The display device according to claim 17, wherein the plurality of nano particles are configured to absorb light emitted from the light emitting layer and output infrared ray or near-infrared ray.
